(19) United States
(12) Patent Application Publication
(10) Pub. No.: US 2012/0134080 A1
(43) Pub. Date: May 31, 2012

(54) HOUSING AND METHOD FOR MANUFACTURING SAME

(75) Inventors: KAI-RONG LIAO, Shenzhen (CN); CHANG-HAI GU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/046,855

(22) Filed: Mar. 14, 2011

(30) Foreign Application Priority Data
Nov. 29, 2010 (CN) 201010563941.8

(51) Int. Cl. H05K 5/00; B29C 45/14

(52) U.S. Cl. 361/679.01; 264/250

(57) ABSTRACT

A housing for an electronic device includes a front shell including a main body and a screen guard, the screen guard is integrally molded with the main body by insert molding; and a rear shell is integrally molded with the front shell to cooperatively define a compartment therebetween.

### BACKGROUND

1. Technical Field

The disclosure relates to housings and methods for manufacturing the housings.

2. Description of Related Art

A typical housing for electronic devices includes an front shell and a back shell. The front shell and the back shell are separately molded by injection molding, and then are connected together by latching mechanisms. However, a gap may be formed between the front shell and the back shell, which affects the appearance of the housing. Additionally, pollutants may enter the housing through the gap.

Therefore, there is room for improvement within the art.

### BRIEF DESCRIPTION OF THE DRAWINGS

Many aspects of the present disclosure can be better understood with reference to the following drawings. These drawings are not necessarily drawn to scale, the emphasis instead being placed upon clearly illustrating the principles of the present disclosure. Moreover, in the drawings like reference numerals designate corresponding parts throughout the several views. Wherever possible, the same reference numbers are used throughout the drawings to refer to the same or like elements of an embodiment.

FIG. 1 is a schematic view of a housing according to an exemplary embodiment.

FIG. 2 is a cross-sectional view of the housing in FIG. 1.

FIG. 3 is a cross-sectional of an exemplary mold for molding a front shell of the housing.

FIG. 4 is a cross-sectional of an exemplary mold for molding a rear shell of the housing.

### DETAILED DESCRIPTION

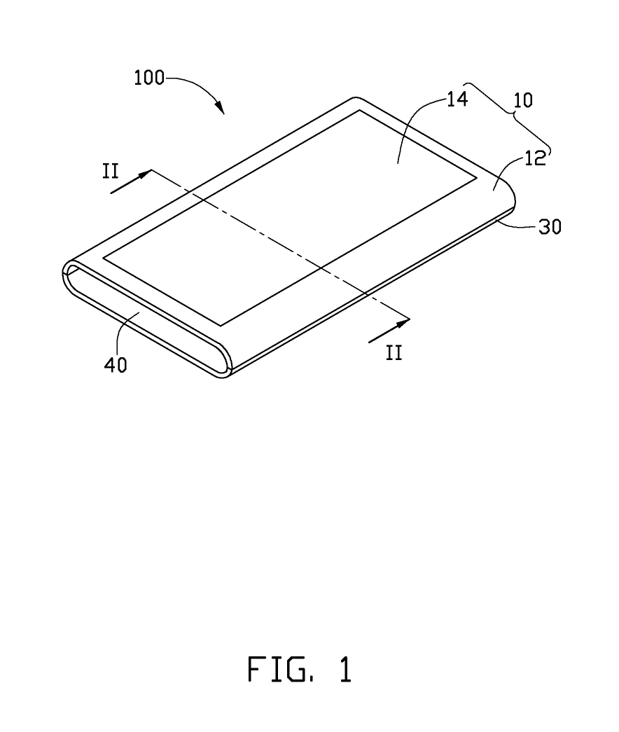

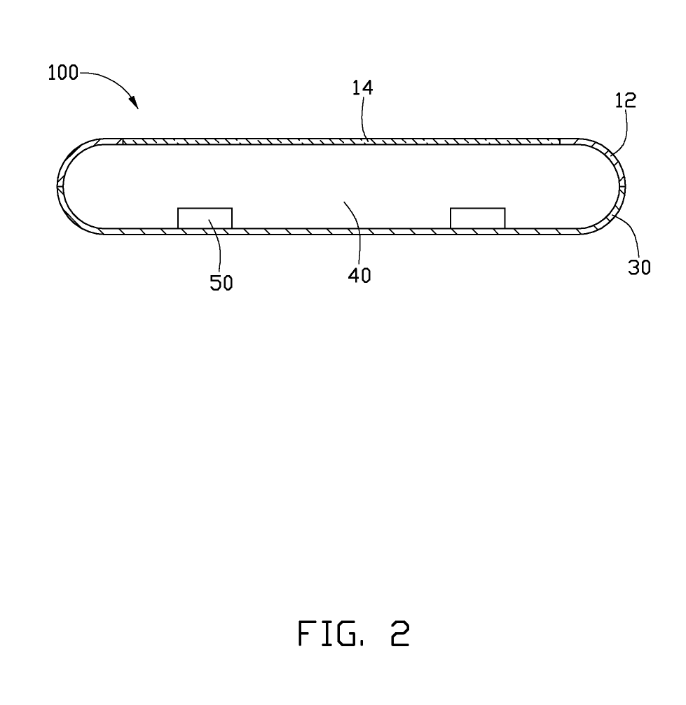

An exemplary embodiment of housing 100 is shown in FIGS. 1 and 2. The housing 100 may be used for an electronic device, such as a mobile phone. The housing 100 is hollow, and includes a front shell 10 and a rear shell 30, which are integrally molded together by insert molding. The front shell 10 and the rear shell 30 cooperatively define a compartment 40 for housing electronic components 50. The housing 100 includes at least an open end to allow the assembly of electronic components 50 in the compartment 40 through the open end. The front shell 10 includes a main body 12 and a screen guard 14 that is integrally molded on the main body 12 by insert molding.

The main body 12 and the rear shell 30 may be both molded by thermosetting plastic, such as one selected from a group of polyethylene, polyvinyl alcohol, polypropylene, polycarbonate, polymethyl methacrylate, acrylonitrile butadiene styrene, and polystyrene.

The screen guard 14 may be made of transparent thermosetting plastic, such as one selected from a group of polycarbonate, polymethyl methacrylate, acrylonitrile butadiene styrene, and polystyrene.

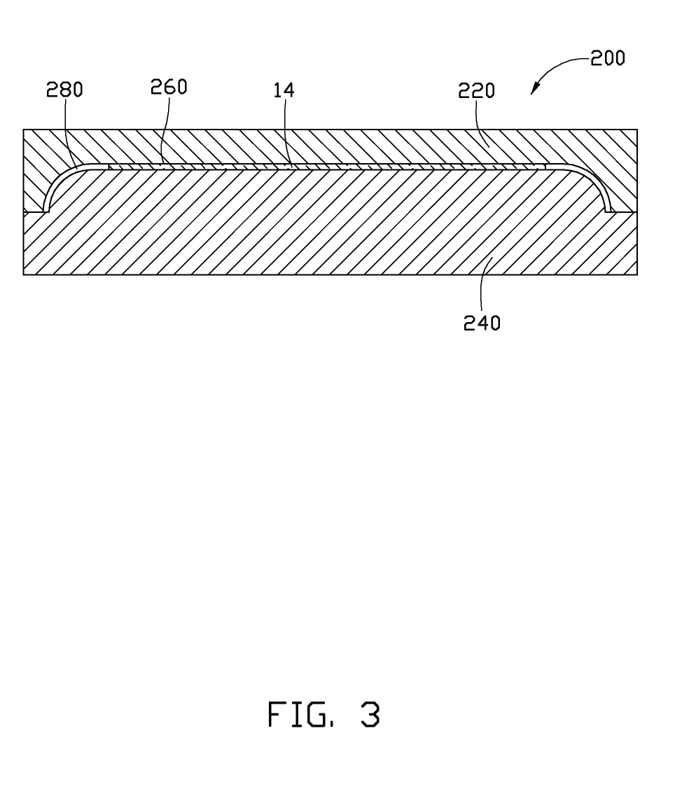

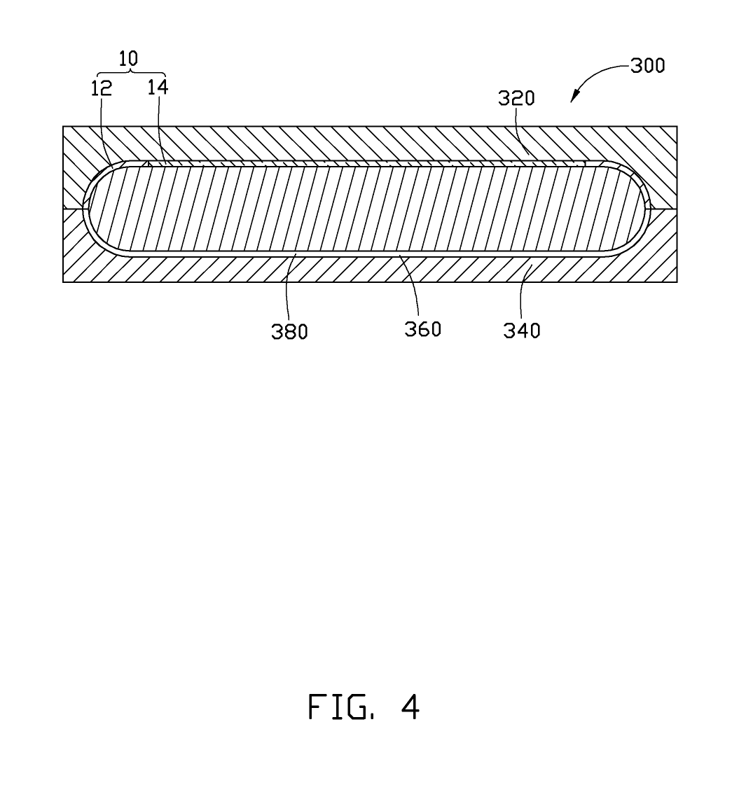

Referring to FIGS. 3-4, a method for manufacturing the housing 100 may include at least the following steps.

A first mold 200 is provided. The first mold 200 includes a first female mold portion 220 and a first male mold portion 240, that together cooperatively define a first mold cavity 260. The first mold cavity 260 has the same shape and size as the front shell 10.

A screen guard 14 is provided. The screen guard 14 may be made of transparent thermosetting plastic, such as one selected from a group of polycarbonate, polymethyl methacrylate, acrylonitrile butadiene styrene, and polystyrene

The screen guard 14 is positioned in the first mold cavity 260, and a first gap 280 is formed between the first mold 200 and the screen guard 14 corresponding to the main body 12.

Liquid thermosetting plastic is injected into the first cavity 260 to fill the first gap 280 thereby forming the main body 12 on the screen guard 14 to manufacture a front shell 10. The liquid thermosetting plastic may be one selected from a group of polyethylene, polyvinyl alcohol, polypropylene, polycarbonate, polymethyl methacrylate, acrylonitrile butadiene styrene, and polystyrene.

A second mold 300 is provided. The second mold 300 includes a second female mold portion 320 and a second male mold portion 340, that together cooperatively define a second mold cavity 360. The second mold cavity 360 has the same shape and size as the housing 100.

The front shell 10 is positioned in the second cavity 360, and a second gap 380 is formed between the second mold 300 and the front shell 10 corresponding to the rear shell 30.

Liquid thermosetting plastic is injected into the second mold cavity 360 to fill the second gap 380 thereby forming the rear shell 30 on the main body 12 to manufacture a housing 100. The liquid thermosetting plastic may be one selected from a group of polyethylene, polyvinyl alcohol, polypropylene, polycarbonate, polymethyl methacrylate, acrylonitrile butadiene styrene, and polystyrene.

In this disclosure, the screen guard 14, the front shell 10 and the rear shell 30 are integrally molded together by insert molding, thereby preventing pollutants from entering the housing 100 between the screen guard 14, the front shell 10 and the rear shell 30.

It is to be understood, however, that even through numerous characteristics and advantages of the exemplary embodiments have been set forth in the foregoing description, together with details of the structure and function of the invention, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing for an electronic device, comprising:
a front shell including a main body and a screen guard, the screen guard integrally molded with the main body by insert molding; and
a rear shell integrally molded with the front shell to cooperatively define a compartment therebetween, the housing being tubular.

2. The housing as claimed in claim 1, wherein the main body and the rear shell are both molded by thermosetting plastic.

3. The housing as claimed in claim 2, wherein the thermosetting plastic is one selected from a group of polyethylene, polyvinyl alcohol, polypropylene, polycarbonate, polymethyl methacrylate, acrylonitrile butadiene styrene, and polystyrene.

4. The housing as claimed in claim 1, wherein the screen guard is made of transparent thermosetting plastic.

5. The housing as claimed in claim 4, wherein the transparent thermosetting plastic is one selected from a group of polycarbonate, polymethyl methacrylate, acrylonitrile butadiene styrene, and polystyrene.

6. A method for manufacturing a housing of an electronic device, comprising:
providing a first mold, the first mold comprising a first female mold portion and a first male mold portion, the first female mold portion and the first male mold portion together cooperatively defining a first mold cavity;
providing a screen guard;
inserting the screen guard in the first mold cavity to form a first gap between the screen guard and the first mold;
injecting liquid thermosetting plastic into the first gap;
curing the thermosetting plastic to form a main body on the screen guard to forming a front cover;
providing a second mold, the second mold comprising a second female mold portion and a second male mold portion, the second female mold portion and the second male mold portion together cooperatively define a second mold cavity;
inserting the front shell in the second mold cavity to form a second gap between the front shell and the second mold;
injecting liquid thermosetting plastic into the second gap;
curing the thermosetting plastic to form a rear shell on the front shell to forming the housing.

7. The method as claimed in claim 6, wherein the main body and the rear shell are both molded by thermosetting plastic.

8. The method as claimed in claim 7, wherein the thermosetting plastic is one selected from a group of polyethylene, polyvinyl alcohol, polypropylene, polycarbonate, polymethyl methacrylate, acrylonitrile butadiene styrene, and polystyrene.

9. The method as claimed in claim 6, wherein the screen guard is made of transparent thermosetting plastic.

10. The method as claimed in claim 9, wherein the transparent thermosetting plastic is one selected from a group of polycarbonate, polymethyl methacrylate, acrylonitrile butadiene styrene, and polystyrene.
